(19) United States
(12) Patent Application Publication
(10) Pub. No.: US 2023/0163102 A1
(43) Pub. Date: May 25, 2023

(54) BONDING STRUCTURE AND MANUFACTURING METHOD THEREFOR

(71) Applicant: Wuhan Xinxin Semiconductor Manufacturing Co., Ltd., Wuhan, Hubei (CN)

(72) Inventors: Di ZHAN, Wuhan, Hubei (CN); Xing HU, Wuhan, Hubei (CN); Tianjian LIU, Wuhan, Hubei (CN); Sheng HU, Wuhan, Hubei (CN)

(73) Assignee: Wuhan Xinxin Semiconductor Manufacturing Co., Ltd., Wuhan, Hubei (CN)

(21) Appl. No.: 17/799,112

(22) PCT Filed: Mar. 24, 2020
(86) PCT No.: PCT/CN2020/080806

§ 371 Date: Aug. 11, 2022

(30) Foreign Application Priority Data
Feb. 25, 2020 (CN) 202010115676.0

(51) Int. Cl. H01L 25/065; H01L 25/00; H01L 23/48; H01L 21/768; H01L 23/00

(52) U.S. Cl. CPC H01L 25/0657; H01L 25/50; H01L 23/481; H01L 21/76898; H01L 24/94; H01L 24/05; H01L 24/08; H01L 24/80; H01L 2225/06544; H01L 2225/06596; H01L 2224/05686; H01L 2924/04642; H01L 2924/0504; H01L 2924/0544; H01L 2224/05647; H01L 2224/08145; H01L 2224/80379; H01L 2224/80357; H01L 2224/80896; H01L 24/09; H01L 2224/09181; H01L 2224/94

(57) ABSTRACT

A bonding structure and a method for manufacturing the same. The bonding structure includes a wafer stack formed by multiple wafers that are bonded in sequence, where: chip stacks are arranged in an array in the wafer stack, and each of the chip stacks includes multiple layers of chips that are bonded in sequence; electrical vertical interconnections are formed in each of the chip stacks; and the electrical vertical interconnections include a thorough vertical interconnection that is electrically connected to an interconnection layer in each of the multiple layers, and a partial vertical interconnection that is electrically connected to the interconnection layer in each of a part of the multiple layers and/or a single vertical interconnection that is electrically connected to the interconnection layer in a single layer of the multiple layers.

This application claims priority to Chinese Patent Application No. 202010115676.0, titled “BONDING STRUCTURE AND METHOD FOR MANUFACTURING THE SAME”, filed on Feb. 25, 2020 with the China National Intellectual Property Administration, which is incorporated herein by reference in its entirety.

### FIELD

The present disclosure relates to the field of semiconductor devices and semiconductor manufacturing, and in particular to a bonding structure and a method for manufacturing the bonding structure.

### BACKGROUND

As semiconductor technology enters the post-Moore era, chip structures are going three-dimensional on demands of high-degree integration and high performances, and wafer-level packaging techniques are widely applied. The wafer-level packaging technology bonds wafer stacks to shorten a signal transmission path between devices, provide more I/Os, increase chip response speed, and reduce a chip dimension. Moreover, the wafer-level packaging technology can realize interconnection among different technical nodes and different functional chips, which renders designing and processing less difficult and therefore reduces a manufacturing cost. A large quantity of stacked layers increases a probability of chip failures. An electrical performance testing may be performed on a fabricated chip stack to identify a failure therein, but it is difficult to determine which chip layer results in the failure.

### SUMMARY

In view of the above, an objective of the present disclosure is to provide a bonding structure and a method for manufacturing the bonding structure, which enables testing on one or more layers of a chip stack such that a defective chip can be located.

Following technical solutions are provided according to embodiments of the present disclosure in order to achieve the above objective.

A bonding structure is provided, including: a wafer stack formed by multiple wafers that are bonded in sequence, where: chip stacks are arranged in an array in the wafer stack, and each of the chip stacks includes multiple layers of chips that are bonded in sequence; electrical vertical interconnections are formed in each of the chip stacks; and the electrical vertical interconnections include a thorough vertical interconnection that is electrically connected to an interconnection layer in each of the multiple layers, and one or both of a partial vertical interconnection that is electrically connected to the interconnection layer in each of a part of the multiple layers and a single vertical interconnection that is electrically connected to the interconnection layer in a single layer of the multiple layers.

In an embodiment, adjacent wafers in the wafer stack are bonded via a dielectric bonding layer, and the electrical vertical interconnections include through silicon vias and a rewiring layer connected to the through silicon vias.

In an embodiment, at least one of the rewiring layers is connected to the through silicon vias that penetrate to different depths.

In an embodiment, adjacent wafers in the wafer stack are bonded via a hybrid bonding structure, where the hybrid bonding structure includes dielectric bonding layers and metal bonding pads in the dielectric bonding layers, the metal bonding pads of the adjacent wafers are bonded to each other, one of the electrical vertical interconnections includes one of the metal bonding pads and a through silicon via connected to the one of the metal bonding pads, and another of the electrical vertical interconnections includes another through silicon via.

A bonding structure is provided, including a chip stack, where: the chip stack includes multiple layer of chips that are bonded in sequence; electrical vertical interconnections are formed in the chip stack; and the electrical vertical interconnections include an thorough vertical interconnection that is electrically connected to an interconnection layer in each of the multiple layers, and one or both of a partial vertical interconnection that is electrically connected to the interconnection layer in each of a part of the multiple layers and a single vertical interconnection that is electrically connected to the interconnection layer in a single layer of the multiple layers.

A method for manufacturing a bonding structure is provided, including: providing a bottom wafer, where chips are arranged in an array in the bottom wafer, and a dielectric bonding layer is formed on the bottom wafer; providing each to-be-bonded wafer, where other chips are arranged in an array in the in each to-be-bonded wafer, and another dielectric bonding layer is formed on each to-be-bonded wafer; bonding each to-be-bonded wafer sequentially on the bottom wafer via the dielectric bonding layer and the another dielectric bonding layer, and forming a through silicon via and a rewiring layer electrically connected to the through silicon via after bonding each to-be-bonded wafer to form a wafer stack including an array of chip stacks and electrical vertical interconnections in each of the chip stacks, where the electrical vertical interconnections include an thorough vertical interconnection that is electrically connected to an interconnection layer in each of multiple layers of chips, and one or both of a partial vertical interconnection that is electrically connected to the interconnection layer in each of a part of the multiple layers and a single vertical interconnection that is electrically connected to the interconnection layer in a single layer of the multiple layers.

In an embodiment, at least one of the rewiring layers is connected to the through silicon vias that penetrate to different depths.

In an embodiment, the method further includes forming a pad on a topmost rewiring layer.

In an embodiment, the method further includes dicing the wafer stack to separate the chip stacks.

A method for manufacturing a bonding structure, including: providing a bottom wafer, where chips are arranged in an array in the bottom wafer, a hybrid bonding structure is formed on the bottom wafer, the hybrid bonding structure includes a dielectric bonding layer and a metal bonding pad in the dielectric bonding layer, and a part of an interconnection layer in the bottom wafer is electrically connected to the metal bonding pad; providing each to-be-bonded wafer, where other chips are arranged in an array in each to-be-bonded wafer, another hybrid bonding structure is formed on the to-be-bonded wafer, and a part of another interconnection layer in each to-be-bonded wafer is electrically connected to another metal bonding pad; bonding each to-be-bonded wafer sequentially on the bottom wafer via the hybrid bonding structure and the another hybrid bonding structure, and forming through silicon vias after each to-be-bonded wafer is bonded to form a wafer stack including an array of chip stacks and electrical vertical interconnections in each of the chip stacks; where when a quantity of the to-be-bonded wafer is more than one, after forming the through silicon vias, the method further includes: forming a new hybrid bonding structure on the through silicon vias, where the new hybrid bonding structure includes a new dielectric bonding layer and a new metal bonding pad in the new dielectric bonding layer, and one of the through silicon vias in said to-be-bonded wafer is electrically connected to the new metal bonding pad; and where the electrical vertical interconnections include an thorough vertical interconnection that is electrically connected to an interconnection layer in each of multiple layers of chips, and one or both of a partial vertical interconnection that is electrically connected to the interconnection layer in each of a part of the multiple layers and a single vertical interconnection that is electrically connected to the interconnection layer in a single layer of the multiple layers.

In an embodiment, after forming the through silicon vias, the method further includes forming a rewiring layer on the through silicon vias.

In an embodiment, the method further includes forming a pad on a topmost rewiring layer.

In an embodiment, the method further includes dicing the wafer stack to separate the chip stacks.

The bonding structure is provided in embodiments of the present disclosure. The wafer stack is formed by the multiple wafers that are bonded in sequence, the chip stacks are arranged in an array in the wafer stack, and each of the chip stacks includes the multiple layers of chips that are bonded in sequence. The electrical vertical interconnections are formed in each of the chip stacks. The electrical vertical interconnections include the thorough vertical interconnection that is electrically connected to an interconnection layer in each of the multiple layers, and the partial vertical interconnection that is electrically connected to the interconnection layer in each of the part of the multiple layers and/or the single vertical interconnection that is electrically connected to the interconnection layer in the single layer of the multiple layers. The thorough vertical interconnection enables a test on an electrical performance of the whole wafer stack. The partial vertical interconnection enables a test on an electrical performance of some layers of chips in the wafer stack, and/or the single vertical interconnection enables a test on an electrical performance of a single layer of chip(s) in the wafer stack, such that the electrical performance can be tested with respect to a single layer or multiple layers of chips in the chip stack. Thereby, a defective chip can be located.

### BRIEF DESCRIPTION OF THE DRAWINGS

For clearer illustration of the technical solutions according to embodiments of the present disclosure or conventional techniques, hereinafter briefly described are the drawings to be applied in embodiments of the present disclosure or conventional techniques. Apparently, the drawings in the following descriptions are only some embodiments of the present disclosure, and other drawings may be obtained by those skilled in the art based on the provided drawings without creative efforts.

FIG. 1 to FIG. 15 show schematic structural diagrams during manufacturing a bonding structure according to an embodiment of the present disclosure.

### DETAILED DESCRIPTION

In order to make objectives, features and advantages of the present disclosure clear and easy to comprehend, hereinafter embodiments of the present disclosure are described in detail in conjunction with the drawings.

Many specific details are illustrated in following description to facilitate a full understanding of the present disclosure. The present disclosure may be practiced in another manner besides those described herein. Those skilled in the art can analogize without departing from the scope of the present disclosure. Therefore, the present disclosure is not limited to specific embodiments disclosed hereinafter.

The present disclosure is described in detail in conjunction with the drawings. To facilitate description in describing embodiments of the present disclosure in detail, a sectional view showing a structure of a device is not partially enlarged on a general scale. The schematic diagram is merely exemplary, and the protection scope of present disclosure should not be limited thereto. In addition, the three-dimensional spatial dimensions of length, width and depth should be included in practical manufacture.

As described in the background, as semiconductor technology enters the post-Moore era, chip structures are going three-dimensional on demands of high-degree integration and high performances, and wafer-level packaging techniques are widely applied. The wafer-level packaging technology bonds wafer stacks to shorten a signal transmission path between devices, provide more I/Os, increase chip response speed, and reduce a chip dimension. Moreover, the wafer-level packaging technology can realize interconnection among different technical nodes and different functional chips, which renders designing and processing less difficult and therefore reduces a manufacturing cost. A large quantity of stacked layers increases a probability of chip failures. An electrical testing may be performed on a fabricated chip stack to identify a failure therein, but it is difficult to determine which chip layer results in the failure.

In view of the above, a bonding structure is provided according to embodiments of the present disclosure. A wafer stack is formed by multiple wafers that are bonded in sequence, chip stacks are arranged in an array in the wafer stack, and each of the chip stacks includes multiple layers of chips that are bonded in sequence. Electrical vertical interconnections are formed in each of the chip stacks. The electrical vertical interconnections include a thorough vertical interconnection that is electrically connected to an interconnection layer in each of the multiple layers, and a partial vertical interconnection that is electrically connected to the interconnection layer in each of a part of the multiple layers and/or a single vertical interconnection that is electrically connected to the interconnection layer in a single layer of the multiple layers. The thorough vertical interconnection enables a test on an electrical performance of the whole wafer stack. The partial vertical interconnection enables a test on an electrical performance of some layers of chips in the wafer stack, and/or the single vertical interconnection enables a test on an electrical performance of a single layer of chip(s) in the wafer stack, such that the electrical performance can be tested with respect to a single layer or multiple layers of chips in the chip stack. Thereby, a defective chip can be located.

For better understanding of technical solutions and technical effects of embodiments of the present disclosure, hereinafter some embodiments are described in detail in conjunction with the drawings.

In an embodiment, a wafer stack is formed by multiple wafers that are bonded in sequence, chip stacks are arranged in an array in the wafer stack, and each of the chip stacks includes multiple layers of chips that are bonded in sequence. Electrical vertical interconnections are formed in each of the chip stacks. The electrical vertical interconnections include a thorough vertical interconnection that is electrically connected to an interconnection layer in each of the multiple layers, and a partial vertical interconnection that is electrically connected to the interconnection layer in each of a part of the multiple layers and/or a single vertical interconnection that is electrically connected to the interconnection layer in a single layer of the multiple layers.

In an embodiment, the wafer stack may be formed by bonding two or more wafers sequentially, and multiple chips are arranged in an array in each wafer. When the wafers are bonded to form the wafer stack, the chips in the wafers are bonded to form the chip stacks, and hence the chip stacks are arranged in an array in the wafer stack. A device structure and an interconnection structure electrically connected to the device structure may have been formed on a substrate for each layer of chip(s) in the chip stack. The device structure may be of a MOS device, a memory device and/or other passive devices. Device structures may be the same as or different in each layer of chips. The device structure is covered by a dielectric bonding layer. The dielectric layer may include a single layer or multiple layers, and may include, for example, an inter-layer dielectric layer and an inter-metal dielectric layer. The dielectric bonding layer may be made of a dielectric material for bonding, such as silicon oxide (bonding oxide), silicon nitride, NDC (nitrogen-doped silicon carbide), or a combination thereof. The interconnection layer is formed in the dielectric bonding layer. The interconnection structure may include multiple layers, and these layers may be connected to each other via contact plugs, wiring layers, vias, or the like. The interconnection layer may be made of metal, such as tungsten, aluminum, or copper.

An electrical vertical interconnection may be formed in the chip stack. The electrical vertical interconnection is connected to the interconnection layer(s), so that interconnection among the device structures of the multiple layers of chips may be implemented. The electrical vertical interconnections include the thorough vertical interconnection, and the partial vertical interconnection and/or the single vertical interconnection. The thorough vertical interconnection can implement interconnection among all layers of chips in the chip stack, and hence enables a test on an electrical performance of all layers of chips. The partial vertical interconnection can implement interconnection among a part of the layers of chips in the chip stack, and hence enables a test on an electrical performance of the part of the layers. The single vertical interconnection can serve as a lead for a single layer of chip(s) in the wafer stack, and hence enables a test on an electrical performance of the single layer.

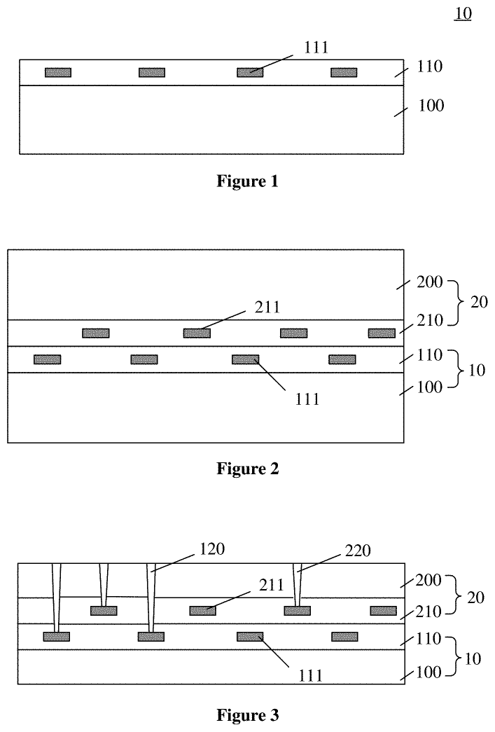

Hereinafter different embodiments of the bonding structure are illustrated in detail in conjunction with FIG. 1 to FIG. 15. The present disclosure is not limited to these embodiments. By using the method and technical content as disclosed above, those skilled in the art can make various possible variations and on technical solutions of the present disclosure or acquire equivalent embodiments without departing from the scope of technical solutions of the present disclosure.

### First Embodiment

In this embodiment, adjacent wafers in the wafer stack are bonded via a dielectric bonding layer. The electrical vertical interconnection includes a through silicon via (TSV) and a rewiring layer connected to the through silicon via. The chip stacks are disposed in an array in the wafer stack, and the electrical vertical interconnections are formed in the chip stack through a TSV technique. Hence, an electrical performance of a single chip or multiple chips in the chip stack of the wafer stack can be tested.

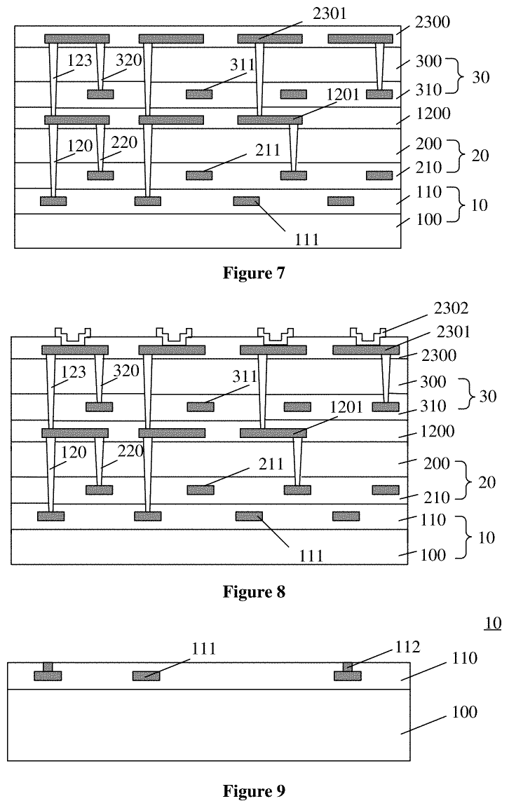

It is taken as an example that a quantity of the wafers is three to illustrate the bonding structure in detail. A first wafer and a second wafer are bonded to each other via a first dielectric bonding layer 110 and a second dielectric bonding layer 210, and the second wafer and a third wafer are bonded to each other via a first cover layer 1200 and a third dielectric bonding layer 310. Chips on the wafers are sequentially bonded to form the chip stack when the wafers are bonded to form the wafer stack, such that the chips stacks are arranged in an array in the wafer stack. Herein only one of the chip stacks in the wafer stack is described in detail. In order to facilitate description, the three layers of chips in such chip stack are called a first chip 10, a second chip 20, and a third chip 30, respectively. Reference is made to FIG. 7.

In an embodiment, the electrical vertical interconnections formed in the chip stack include TSVs and rewiring layers connected to the TSVs. The electrical vertical interconnections may include a thorough vertical interconnection which is electrically connected to the interconnection layers of all layers of chips, and a partial vertical interconnection which is electrically connected to the interconnection layers of a part of the layers, such as two layers of chips, and/or a single vertical interconnection which is electrically connected to the interconnection layer of a single layer.

The thorough vertical interconnection that is electrically connected to the interconnection layers of all layers may include a TSV 120 penetrating to an interconnection layer 111 in the first chip 10, a TSV 220 penetrating to an interconnection layer 211 in the second chip 20, a TSV 320 penetrating to an interconnection layer 311 in the third chip 30, a first rewiring layer 1201, and a second rewiring layer 2301. The first rewiring layer 1201 connects the TSV 120 and the TSV 220, which are adjacent and penetrate downward to different depths, thereby connecting the first chip 10 and the second chip 20. The second rewiring layer 2301 connects the TSV 123 and the TSV 320, which are adjacent and penetrate downward to different depths, and the TSV 123 connects the first rewiring layer 1201 and the second rewiring layer 2301, such that the TSV 120, the TSV 220 and the TSV 320 are connected via the first rewiring layer 1201 and the second rewiring layer 2301. Therefore, the first chip 10, the second chip 20, and the third chip 30 are interconnected, and an electrical performance of such chip stack in the wafer stack may be tested. Passing the test indicates that all chips in the chip stack are qualified, and a process such as packaging may be subsequently performed. Failing the test indicates that there is a defective chip in the chip stack, and single layers or a part of the layers in the chip stack may be further tested to locate the defective chip.

The partial vertical interconnection that is connected to the interconnection layers of a part of the layers may include the TSV 120, the TSV 220, the TSV 123, the first rewiring layer 1201, and the second rewiring layer 2301. The first rewiring layer 1201 connects the TSV 120 and the TSV 220, which are adjacent and penetrate to different depths, thereby connecting the first chip 10 and the second chip 20. The TSV 123 and the second rewiring layer 2301 further provide an outside contact for the first chip 10 and the second chip 20. Hence, electrical performances of the first chip 10 and the second chip 20 can be jointly tested. Passing the test indicates that the first chip 10 and the second chip 20 are both qualified. Failing the test indicates that one or both of the first chip 10 and the second chip 20 are defective, and the first chip 10 and the second chip 20 may be further tested separately to locate the defective chip(s).

Additionally or alternatively, the partial vertical interconnection that is connected to the interconnection layers of a part of the layers may include the TSV 120, the TSV 123, the TSV 320, the first rewiring layer 1201, and the second rewiring layer 2301. The first rewiring layer 1201 connects the TSV 120 and the TSV 123, and the second rewiring layer 2301 connects the TSV 123 and the TSV 320, which are adjacent and penetrate to different depths, thereby connecting the first chip 10 and the third chip 30. Hence, electrical performances of the first chip 10 and the third chip 30 can be jointly tested. Passing the test indicates that the first chip 10 and the third chip 30 are both qualified. Failing the test indicates that one or both of the first chip 10 and the third chip 30 are defective, and the first chip 10 and the third chip 30 may be further test separately to locate the defective chip(s).

Additionally or alternatively, the partial vertical interconnection that is connected to the interconnection layers of a part of the layers may include the TSV 220, the TSV 123, the TSV 320, the first rewiring layer 1201, and the second rewiring layer 2301. The first rewiring layer 1201 connects the TSV 220 and the TSV 123, and the second rewiring layer 2301 connects the TSV 123 and the TSV 320, which are adjacent and penetrate to different depths, thereby connecting the second chip 20 and the third chip 30. Hence, electrical performances of the second chip 20 and the third chip 30 can be jointly tested. Passing the test indicates that the second chip 20 and the third chip 30 are both qualified. Failing the test indicates that one or both of the second chip 20 and the third chip 30 are defective, and the second chip 20 and the third chip 30 may be further tested separately to locate the defective chip(s).

The single vertical interconnection that is connected to the interconnection layer of a single layer may include the TSV 120, the TSV 123, the first rewiring layer 1201, and the second rewiring layer 2301. The first rewiring layer 1201 connects the TSV 123 and the TSV 120, and the second rewiring layer 2301 connected to the TSV 123 further provides an outside contact for the interconnection layer 111 in the first chip 10. Hence, an electrical performance of the first chip 10 in the chip stack can be tested.

Additionally or alternatively, the single vertical interconnection that is connected to the interconnection layer of a single layer may include the TSV 220, the TSV 123, the first rewiring layer 1201, and the second rewiring layer 2301. The first rewiring layer 1201 connects the TSV 220 and the TSV 123, and the second rewiring layer 2301 connected to the TSV 123 further provides an outside contact for the interconnection layer 211 in the second chip 20. Hence, an electrical performance of the second chip 20 in the chip stack can be tested.

Additionally or alternatively, the single vertical interconnection that is connected to the interconnection layer of a single layer may include the TSV 320 and the second rewiring layer 2301. The second rewiring layer 2301 is connected to the TSV 320, and thereby provides an outside contact for the interconnection layer 311 in the third chip 30. Hence, an electrical performance of the third chip 30 in the chip stack can be tested.

In the foregoing embodiments, the electrical vertical interconnections, which include TSVs and rewiring layers connected to the TSV, of the bonding structure are formed in the chip stack through a TSV technique. Hence, an electrical performance of a single layer in the chip stack may be tested, or electrical performances of a part the layers in the chip stack may be jointly tested, so as to locate the defective chip(s). Accordingly, the defective chip can be bypassed to utilize only qualified chips, which reduces a rejection rate.

### Second Embodiment

In this embodiment, adjacent wafers in the wafer stack are bonded via a hybrid bonding structure. The hybrid bonding structure includes a dielectric bonding layer and a metal bonding pad in the dielectric bonding layer. The metal bonding pads of adjacent wafers are bonded to each other. One of the electrical vertical interconnections includes the metal bonding pad and a TSV connected to the metal bonding pad, and another of the electrical vertical interconnections includes another TSV. After the wafers in the wafer stack are subject to hybrid bonding, the electrical vertical interconnection including the metal bonding pad and the TSV connected to the metal bonding pad, or the electrical vertical interconnection including the other TSV, are formed through a TSV technique. Hence, an electrical performance of a single layer or multiple layers may be tested in the chip stacks that are arranged in an array on a wafer stack.

In this embodiment, adjacent wafers are bonded via the hybrid bonding structure, and the “hybrid” bonding structure refer to that a bonding interface is formed by different bonding materials. Herein the hybrid bonding structure includes the dielectric bonding layer and the metal bonding pad in the dielectric bonding layer. The metal bonding pad is electrically connected to the interconnection layer in such dielectric bonding layer, and may be formed directly on the interconnection layer, so as to implement electrical connection among the chips in a wafer or provide an outside contact for the interconnect layer in a chip. The dielectric bonding layer is made of a dielectric material for bonding, and may be of a single-layer or multi-layer structure. For example, the dielectric material may be silicon oxide (bonding oxide), silicon nitride, NDC (Nitrogen doped Silicon Carbide) or a combination thereof. The metal bonding pad may be made of a metal material for bonding, such as copper.

Reference is made to FIG. 14. It is taken as an example that a quantity of the wafers is three to illustrate the bonding structure in detail. In order to facilitate description, the three wafers are called a first wafer, a second wafer and a third wafer, respectively. A first dielectric bonding layer 110 in the first wafer is bonded to a second dielectric bonding layer 210 in the second wafer, and a first metal bonding pad 112 in the first dielectric bonding layer 110 is bonded to a second metal bonding pad 212 in the second dielectric bonding layer 210, so as to implement bonding between the first wafer and the second wafer. A first cover layer 1200 on the second wafer is bonded to a third dielectric bonding layer 310 in the third wafer, and a metal bonding pad 1202 in the first cover layer 1200 is bonded to a third metal bonding pad 312 in the third dielectric bonding layer 310, so as to implement bonding between the second wafer and the third wafer. Hence, the wafer stack including the three wafers is formed. Other wafers may be further bonded on the third wafer to form a wafer stack having more wafers. In an embodiment, the metal bonding pad and the interconnection layer in the same dielectric bonding layer may be simultaneously formed.

In embodiments of the present disclosure, the chips on the wafers are bonded to form chip stacks when the wafers are bonded to form the wafer stack, such that the chip stacks are arranged in an array in the wafer stack. Herein only one chip stack in the wafer stack is described in detail. In order to facilitate description, the three chips in such chip stack are called a first chip 10, a second chip 20, and a third chip 30, respectively. Reference is made to FIG. 14.

In an embodiment, one of the electrical vertical interconnections that are formed in the chip stack includes a metal bonding pad and a TSV connected to the metal bonding pad, and another of the electrical vertical interconnections includes another TSV. The electrical vertical interconnections may include a thorough vertical interconnection which is electrically connected to the interconnection layers of all layers of chips, and a partial vertical interconnection that is connected to the interconnection layers of a part of the layers or a single vertical interconnection that is connected to the interconnection layer of a single layer.

In an embodiment as shown in FIG. 14, the thorough vertical interconnection that is electrically connected to the interconnection layers in all layers of chips may include a first metal bonding pad 112, a second metal bonding pad 212, a TSV 220, a first rewiring layer 1201, a metal bonding pad 1202 on the first rewiring layer 1201, a third metal bonding pad 312, a TSV 123, and a second rewiring layer 2301. The first metal bonding pad 112 is bonded to the second metal bonding pad 212 to implement interconnection between the first chip 10 and the second chip 20. The TSV 220 is connected to the first rewiring layer 1201, the metal bonding pad 1202 on the first rewiring layer 1201 is connected to the third metal bonding pad 312 for the third chip 30, thereby connecting interconnection layer 111 in the first chip 10, an interconnection layer 211 in the second chip 20, and an interconnection layer 311 in the third chip 30. Hence, interconnection is implemented among the first chip 10, the second chip 20, and the third chip 30. The second rewiring layer 2301 connected to the TSV 123 further provides an outside contact for the chip stack. Thereby, the electrical vertical interconnection including the metal bonding pads and the TSVs connected to the metal bonding pads is formed, which enables a test on an electrical performance of the chip stack. Passing the test indicates that all chips in the chip stack are qualified. Failing the test indicates that an electrical performance of one or two layers in the chip stack may be further tested in the chip stack to locate the defective chip(s).

The partial vertical interconnection that is electrically connected to the interconnection layers of a part of the layers may include a first metal bonding pad 112, a second metal bonding pad 212, and a TSV on the second metal bonding pad 212. The first metal bonding pad 112 is bonded to the second metal bonding pad 212, implementing interconnection between the first chip 10 and the second chip 20. A TSV 220 penetrating to an interconnection layer 211 on the second metal bonding pad 212, a TSV 320, a first rewiring layer 1201, and a second rewiring layer 2301 are further provided to form the partial vertical interconnection including TSVs and metal bonding pads. The first rewiring layer 1201 connects the TSV 220 and the TSV 320, and the second rewiring layer 2301 connected to the TSV 320 provides an outside contact for the first chip 10 and the second chip 20. Hence, electrical performances of the first chip 10 and the second chip 20 can be jointly tested.

Alternatively or additionally, the partial vertical interconnection that is electrically connected to the interconnection layers of a part of the layers may include a TSV 220 penetrating to an interconnection layer 211 in the second chip 20, a first rewiring layer 1201, a metal bonding pad 1202 on the first rewiring layer, a third metal bonding pad 312 in the third chip 30, a TSV 123 penetrating to an interconnection layer 311 in the third chip 30, and a second rewiring layer 2301. The metal bonding pad 1202 on the first rewiring layer 1201 is bonded to the third metal bonding pad 312, further provides an outside contact for the interconnection layer 211 in the second chip 20 via the TSV 220, and connected to the second rewiring layer 2301 is made via the TSV 123 to form the partial vertical interconnection connecting the second chip 20 and the third chip 30. Hence, electrical performances of the second chip 20 and the third chip 30 can be tested jointly.

Alternatively or additionally, the partial vertical interconnection that is electrically connected to the interconnection layers of a part of the layers may include a TSV 120 penetrating to an interconnection layer 111 in the first chip 10, a first rewiring layer 1201, a metal bonding pad 1202 on the first rewiring layer 1201, a third metal bonding pad 312 in the third chip 30, a TSV 123 penetrating to an interconnection layer 311 in the third chip 30, and a second rewiring layer 2301. The metal bonding pad 1202 on the first rewiring layer 1201 is bonded to the third metal bonding pad 312 and is connected to the TSV 120, so that the interconnection layer 111 in the first chip 10 is connected to the interconnection layer 311 in the third chip 30. Further, the TSV 123 and the second rewiring layer 2301 connected to the TSV 123 provide an outside contact for the interconnection layers in the first chip 10 and the third chip 30 to form the partial vertical interconnection connecting the first chip 10 and the third chip 30. Hence, electrical performances of the first chip 10 and the third chip 30 can be tested jointly.

The single vertical interconnection that is electrically connected to the interconnection layer of a single layer may include a TSV 120 penetrating to an interconnection layer 111 in the first chip 10, a TSV 320, a first rewiring layer 1201, and a second rewiring layer 2301. The first rewiring layer 1201 connects the TSV 120 and the TSV 320, and the TSV 320 is connected to the second rewiring layer 2301 to provide an outside contact for the interconnection layer 111 in the first chip 10. Thereby, the single vertical interconnection including TSVs is formed, and an electrical performance of the first chip 10 in the chip stack can be tested.

Alternatively or additionally, the single vertical interconnection that is electrically connected to the interconnection layer of a single layer may include a TSV 220 penetrating to an interconnection layer 211 in the second chip 20, a TSV 320, a first rewiring layer 1201, and a second rewiring layer 2301. The first rewiring layer 1201 connects the TSV 220 and the TSV 320, and further the TSV 320 and the second rewiring layer 2301 provide an outside contact for interconnection layer 211 in the second chip 20 to form the single vertical interconnection including TSVs. Hence, an electrical performance of the second chip 20 in the chip stack can be tested.

Alternatively or additionally, the single vertical interconnection that is electrically connected to the interconnection layer of a single layer may include a TSV 123 penetrating to an interconnection layer 311 in the third chip 30, and a second rewiring layer 2301. The second rewiring layer 2301 provides an outside contact for the interconnection layer 311 in the third chip 30 to form the single vertical interconnection including a TSV. Hence, an electrical performance of the third chip 30 in the chip stack can be tested.

The electrical vertical interconnections of the foregoing bonding structure are formed through in the chip stack through a hybrid bonding technique and a TSV technique. One of the electrical vertical interconnections include the metal bonding pad and the TSV connected to the metal bonding pad, and another of the electrical vertical interconnections includes another TSV. Hence, an electrical performance of a single layer of chip(s) in the chip stack or electrical performances of multiple layers of chips in the chip stack may be tested to locate the defective chip(s).

Afterwards, the bonding structure may be packaged. During the packaging, qualified chips may be selectively connected, while the electrical vertical interconnections connecting the defective chip(s) are avoided in the connection. Hence, the qualified chips can be fully utilized to reduce a rejection rate.

Hereinabove the bonding structure according to embodiments of the present disclosure is illustrated in detail. Another bonding structure is further provided according to embodiments of the present disclosure. Such boding structure includes a chip stack. The chip stack includes multiple layers of chips bonded in sequence. Electrical vertical interconnections are formed in the chip stack. The electrical vertical interconnections include a thorough vertical interconnection which is electrically connected to an interconnection layer of each of the multiple layers, and a partial vertical interconnection which is electrically connected to the interconnection layer of a part of the multiple layers and/or a single vertical interconnection which is electrically connected to the interconnection layer of a single layer of the multiple layers.

In an embodiment, the thorough vertical interconnection enables a test on electrical performances of all layers of chips in the chip stack, the partial vertical interconnection enables a test on electrical performances of some layers of chips in the chip stack, and the single vertical interconnection enables a test on an electrical performance of a certain layer of chip(s) in the chip stack.

In a specific embodiment, electrical performances of all layers that are electrically connected in the chip stack may be first tested via the thorough vertical interconnection. Passing the test indicates that there is no defective chip in the chip stack, and the chip stack may be further processed, for example, packaged in a subsequent step. Failing the test indicates that there is a defective chip in the chip stack, and electrical performances of a part of the layers of chips that are electrically connected may be further tested. In a case that such part of the layers passes the teste, the electrical performances of another part of the layers of chips may be further tested. In a case that such part of the layers of chips fails the test, it indicates that there is the defective chip in such part of the layers, and these layers may be further tested separately via single vertical interconnections, so as to locate the defective chip. It is not necessary to test the electrical performance of each layer in the chip stack, which improves an efficiency of testing the electrical performance.

Hereinabove the bonding structure is described in detail. Hereinafter a method for manufacturing the aforementioned bonding structure is described in detail according to various embodiments in conjunction with FIG. 1 to FIG. 15. The present disclosure is not limited to the following embodiments. By using the method and technical content as disclosed above, those skilled in the art can make various possible variations and on technical solutions of the present disclosure or acquire equivalent embodiments without departing from the scope of technical solutions of the present disclosure.

Herein a method for manufacturing a bonding structure is described in detail in conjunction with FIG. 1 to FIG. 8.

Reference is made to FIG. 1. A bottom wafer is provided, and chips 10 are arranged in an array on the bottom wafer. A dielectric bonding layer 110 is formed on the bottom wafer. Herein the bottom wafer may also be called a first wafer.

Each to-be-bonded wafer is provided. Chips are arranged in an array on each to-be-bonded wafer, and a dielectric bonding layer is formed on each to-be-bonded wafer. Herein the to-be-bonded wafers may be called a second wafer, a third wafer, and the like.

The to-be-bonded wafers are sequentially bonded on the bottom wafer via the dielectric bonding layers. After each to-be-bonded wafer is bonded, a TSV and a rewiring layer electrically connected to the TSV are formed. Thereby, a wafer stack having chip stacks arranged in an array, and electrical vertical interconnections in the chip stacks, are formed. The electrical vertical interconnections include a thorough vertical interconnection which is electrically connected to an interconnection layer of all layers of chips, and a partial vertical interconnection which is electrically connected to the interconnection layer of each of a part of the layers of chips and/or a single vertical interconnection which is electrically connected to the interconnection layer of a single layer of the layers of chips.

Hereinafter the bottom wafer is called a first wafer, and the to-be-bonded wafers are called a second wafer, a third wafer, and the like to clarify the description. Reference is made to FIG. 1, which shows a chip structure, i.e., a first chip 10, in the first wafer. The first wafer and the second wafer are bonded to forming a wafer stack via the dielectric bonding layer 110 on the first wafer and a dielectric bonding layer 210 on the second wafer. In order to facilitate subsequent TSV fabrication, a backside of the substrate 200 of the second wafer may be thinned, for example, through chemical mechanical polishing (CMP) or wet etching (WET). Reference is made to FIG. 2, which shows a structure of a chip stack in the wafer stack formed by bonding the first wafer and the second wafer.

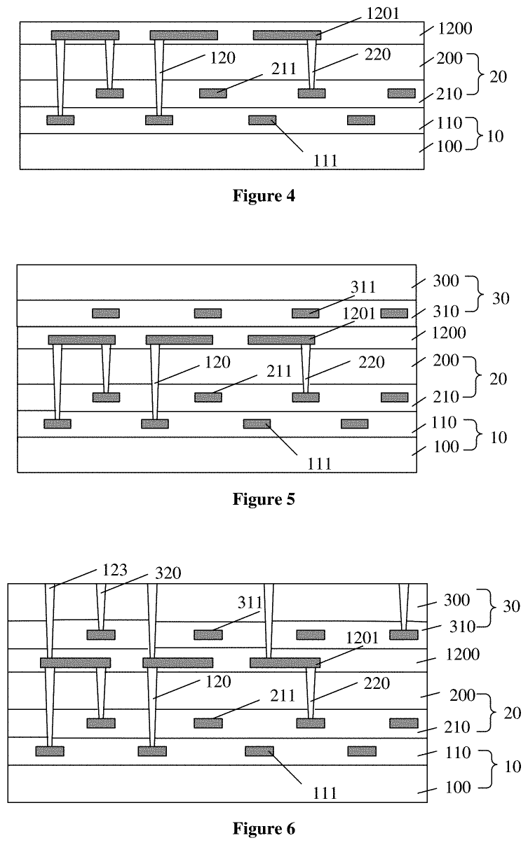

Reference is made to FIG. 3, where TSVs penetrating to the interconnection layers in the chips are formed in the bonded wafers. An insulating dielectric layer may be formed on a sidewall of the TSV, and may be made of silicon oxide, silicon nitride, or the like. The TSV may be then filled with a metal material, such as tungsten, aluminum, or copper. A TSV 120 penetrates to the interconnection layer 111 of the first chip 10 in the first wafer, and a TSV 220 penetrates to the interconnection layer 211 of the second chip 20 in the second wafer. Thereby, the interconnection layers of the first chip 10 in the first wafer and of the second chip 20 in the second wafer can be provided with outside contacts, respectively, which enables a test on electrical performances of the first chip 10 and the second chip 20. Reference is then made to FIG. 4, where a first cover layer 1200 is formed on the second wafer, and a first rewiring layer 1201 is formed in the first cover layer 1200. The first cover layer 1200 may be of a single-layer structure or a multi-layer structure. A material of the first cover layer 1200 may be the same as or different from the material of the dielectric bonding layer. The first rewiring layer 1201 may be made of metal, such as Tungsten, aluminum, or copper. The first rewiring layer 1201 connects the TSV 120 and TSV 220, implementing interconnection between the interconnection layer 111 of the first chip 10 in the first wafer and the interconnection layer 211 of the second chip 20 in the second wafer. Hence, the thorough vertical interconnection that is electrically connected to the interconnection layers of all layers of chips in the chip stack is formed. The TSV 120 is connected to the first rewiring layer 1201, and the TSV 220 is connected to the first rewiring layer 1201, which forms single vertical interconnections that each provides an outside contact for a single layer.

Then, the third wafer is further bonded. A third dielectric bonding layer 310 on the third wafer may be bonded to the first cover layer 1200 to achieve the bonding between the third wafer and the second wafer. Thereby, a wafer stack including three wafers is formed. Reference is made to FIG. 5, which is a structure of one chip stack in the wafer stack including three wafers. The chip stack is subject to TSV fabrication to form a TSV 123 penetrating to the first rewiring layer 1201 and a TSV 320 penetrating to an interconnection layer 311 of the third chip 30 in the third wafer, as shown in FIG. 6. Afterwards, a second cover layer 2300 is formed on the third wafer, and a material of the second cover layer 2300 may be the same as or different from the material of the first cover layer 1200. A second rewiring layer 2301 is formed in the second cover layer 2300. The second rewiring layer 2301 is connected to the TSV 123 and the TSV 320, and thereby the electrical vertical interconnections for the three-layer chip stack are formed, as shown in FIG. 7. The electrical vertical interconnections include a thorough vertical interconnection which is electrically connected to the interconnection layers of all layers of chips, a partial vertical interconnection which is electrically connected to the interconnection layers which is electrically connected to the interconnection layers of a part of the layers of chips, and a single vertical interconnection which is electrically connected to the interconnection layer of a single layer of the layers of chips.

In an embodiment, at least a part of the rewiring layers is connected to TSVs that are adjacent and penetrate to different depths. As shown in FIG. 7, the first rewiring layer 1201 is connected to the TSV 120 and the TSV 220, which are adjacent and penetrate downward to different depths. The second rewiring layer 2301 is connected to the TSV 123 and the TSV 320, which are adjacent and penetrate downward to different depths.

Reference is made to FIG. 8. In an embodiment, a pad 2302 may be formed on the topmost rewiring layer, in order to provide an outside contact for different electrical vertical interconnections. Different electrical vertical interconnections may be selected to implement a test on an electrical performance of the chip stack, of some layers of chips in the chip stack, or of single layers in the chip stack, so as to locate the defective chip(s).

In an embodiment, the wafer stack is diced to obtain the discrete chip stacks after the wafer stack is formed. Electrical performances of the chip stacks may be tested before or after the dicing, so as to filter out the defective chips before subsequent packaging. In an embodiment, the wafer stack may be diced along scribe lines among the chips in the wafer stack, so as to obtain the multiple chip stacks.

Another method for manufacturing a bonding structure is described in detail according to embodiments of the present disclosure in conjunction with FIG. 9 to FIG. 15.

A bottom wafer is provided. Chips are arranged in an array in the wafer stack. A hybrid bonding structure is formed on the bottom wafer, and the hybrid bonding structure includes a dielectric bonding layer 110 and a metal bonding pad 112 in the dielectric bonding layer 110. Reference is made to FIG. 9, where a part of an interconnection layer 111 in the bottom wafer is electrically connected to the metal bonding pad 112. Similar to the foregoing description, hereinafter the bottom wafer is called a first wafer,

Each to-be-bonded wafer is provided. Other chips are arranged in an array in each to-be-bonded wafer, and another hybrid bonding structure is formed on each to-be-bonded wafer. A part of another interconnection layer in the to-be-bonded wafer is electrically connected to another metal bonding pad. The to-be-bonded wafers are called a second wafer, a third wafer, or the like, for consistency of describing embodiments of the present disclosure.

The to-be-bonded wafers are sequentially bonded on the bottom wafer via the hybrid bonding structures. A TSV is formed after each to-be-bonded wafer is bonded. In a case that there are multiple to-be-bonded wafers, the method further includes a following step after the TSV is formed. A new hybrid bonding structure is formed on the TSV. The new hybrid bonding structure includes a new dielectric bonding layer and a new metal bonding pad in the new dielectric bonding layer, and a part of the TSVs in the to-be-bonded wafer is electrically connected to the new metal bonding pad. Thereby, the wafer stack having chip stacks arranged in an array and electrical vertical interconnections in the chip stacks are formed. The electrical vertical interconnections include a thorough vertical interconnection which is electrically connected to an interconnection layer of all layers of chips, and a partial vertical interconnection which is electrically connected to the interconnection layer of each of a part of the layers of chips and/or a single vertical interconnection which is electrically connected to the interconnection layer of a single layer of the layers of chips.

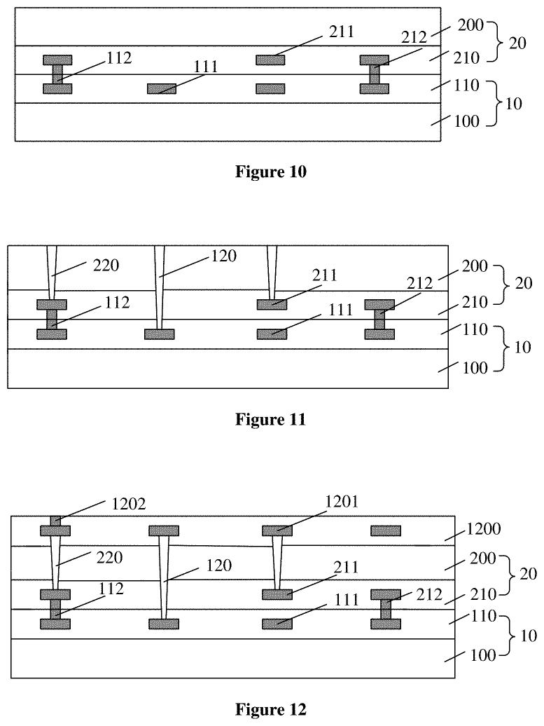

Reference is made to FIG. 10. In an embodiment, the first dielectric bonding layer 110 on the first wafer and the first metal bonding pad 112 in the first dielectric bonding layer 110 are bonded to the second dielectric bonding layer 210 on the second wafer and the second metal bonding pad 212 in the second dielectric bonding layer 210, respectively, so as to form a wafer stack. After the first wafer and the second wafer are bonded, a backside of the substrate 200 of the second wafer may be thinned, for example, through chemical mechanical polishing (CMP) or wet etching (WET), to facilitate subsequent TSV fabrication.

Reference is made to FIG. 11, where TSVs penetrating to interconnection layers in a chip is formed in the wafer stack. A TSV 120 penetrates to the interconnection layer 111 of the first chip 10 in the first wafer, and a TSV 220 penetrates to the interconnection layer 211 of the second chip 20 in the second wafer. Thereby, the first chip 10 and the second chip 20 are provided with respective outside contacts, which enable tests on electrical performances of the first chip 10 in the first wafer and the second chip 20 in the second wafer, respectively. Reference is further made to FIG. 12, where a first cover layer 1200 is formed on the second wafer, and a first rewiring layer 1201 and a first metal bonding pad 1202 on the first rewiring layer 1201 are formed in the first cover layer 1200. The first metal bonding pad 112 is bonded to the second metal bonding pad 212, and further connected to the first rewiring layer 1201 via the TSV 220 connected to the interconnection layer 211, which forms a thorough vertical interconnection for the two-layer chip stack. The TSV 120 is connected to the interconnection layer 111 in the first chip 10, and the TSV 220 is connected to the interconnection layer 211 in the second chip 20, such that single vertical interconnections that are electrically connected to the interconnection layers of the single layers, respectively, are provided.

Then, the third wafer may be bonded. A third dielectric bonding layer 310 on the third wafer may be bonded to the first cover layer 1200, and a third metal bonding pad 312 may bonded to the metal bonding pad 1202 in the first rewiring layer 1201, in order to implement bonding between the second wafer and the third wafer. Thereby, a wafer stack including the three wafers is formed, and each wafer has chips arranged in an array.

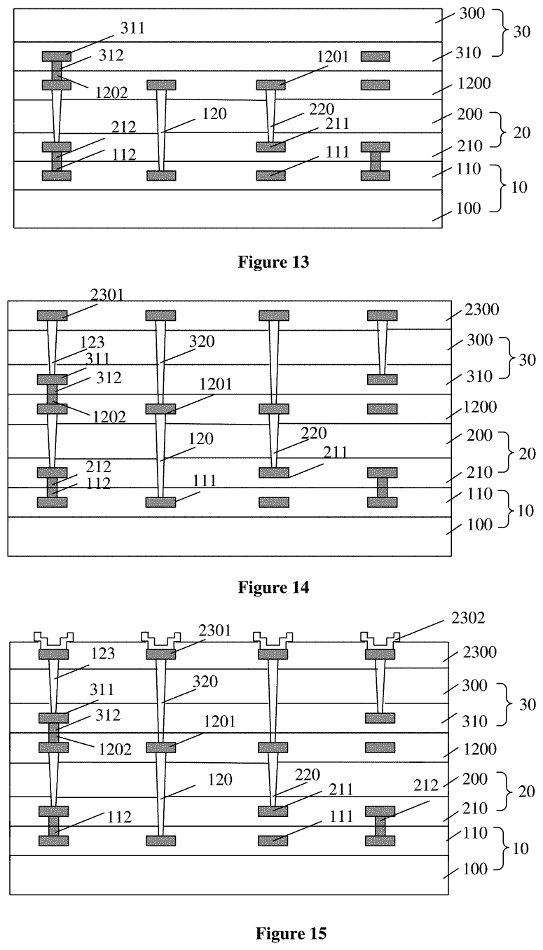

Reference is made to FIG. 13, where the chips in the wafers are bonded form the chip stack when the wafers are bonded to form the wafer stack. Afterwards, the chip stack is subject to TSV fabrication to form a TSV 123 penetrating to an interconnection layer 311 of the third chip 30 in the third wafer and a TSV 320 penetrating to the first rewiring layer 1201. A second rewiring layer 2301 is formed over the TSV 123 and the TSV 320, and the second rewiring layer 2301 is formed in a second cover layer 2300. Reference is made to FIG. 14. Thereby, the electrical vertical interconnections for the three-layer chip stack are formed. The electrical vertical interconnections include a thorough vertical interconnection that is electrically connected to the interconnection layers of all layers of chips, a partial vertical interconnection that is electrically connected to the interconnection layers of a part of the layers of chips, and a single vertical interconnection that is electrically connected to the interconnection layer of a single layer of the layers of chips.

Reference is made to FIG. 15. In an embodiment, a pad 2302 may be formed on the topmost rewiring layer 2301, in order to provide an outside contact for different electrical vertical interconnections. Different electrical vertical interconnections may be selected to implement tests on an electrical performance of the chip stack, of some layers in the chip stack, or a single layer in the chip stack, so as to locate the defective chip(s). Hence, the defective chip can be bypassed to utilize only the qualitied chips, which reduces a rejection rate.

In an embodiment, the wafer stack is diced after being formed, so as to obtain the discrete chip stacks. Electrical performances of the chip stacks may be tested before or after the dicing, so as to filter out the defective chips before subsequent packaging on the qualified chips. In an embodiment, the wafer stack may be diced along scribe lines among the chips in the wafer stack, so as to obtain the multiple chip stacks.

Embodiments of the present disclosure are described in a progressive manner, and one embodiment can refer to other embodiments for the same or similar parts. Each embodiment places emphasis on the difference from other embodiments.

The foregoing embodiments are only preferred embodiments of the present disclosure. The preferred embodiments according to the disclosure are disclosed above, and are not intended to limit the present disclosure. With the method and technical content disclosed above, those skilled in the art can make some variations and improvements to the technical solutions of the present disclosure, or make some equivalent variations on the embodiments without departing from the scope of technical solutions of the present disclosure. All simple modifications, equivalent variations and improvements made based on the technical essence of the present disclosure without departing the content of the technical solutions of the present disclosure fall within the protection scope of the technical solutions of the present disclosure.

1. A bonding structure, comprising a chip stack, wherein:
the chip stack comprises a plurality of layers of chips that are bonded and electrical vertical interconnections;
each layer of the plurality of layers comprises an interconnection layer; and
the electrical vertical interconnections comprises:
a thorough vertical interconnection that is electrically connected to the interconnection layer in each layer of the plurality of layers, and
one or both of:
a partial vertical interconnection that is electrically connected to the interconnection layer in each layer of a part of the plurality of layers, and
a single vertical interconnection that is electrically connected to the interconnection layer in a single layer of the plurality of layers.

2. The bonding structure according to claim 1, wherein:
adjacent chips in the chip stack are bonded via a dielectric bonding layer, and
the electrical vertical interconnections comprise one or more through silicon vias and one or more rewiring layers connected to the one or more through silicon vias.

3. The bonding structure according to claim 2, rewiring layer of the one or more rewiring layers is connected to different through silicon vias of the one or more through silicon vias, and the different through silicon vias are located at a same side of the rewiring layer and have different lengths.

4. The bonding structure according to claim 1, wherein
adjacent chips in the chip stack are bonded via a hybrid bonding structure;
the hybrid bonding structure comprises dielectric bonding layers of the adjacent chips and metal bonding pads in the dielectric bonding layers, respectively;
the metal bonding pads of the adjacent chips are bonded to each other;
one of the electrical vertical interconnections comprises one of the metal bonding pads and a through silicon via connected to the one of the metal bonding pads; and
another of the electrical vertical interconnections includes another through silicon via.

5. A bonding structure, comprising bonding sub-structures, each of which is the bonding structure according to claim 1, wherein:
the bonding structure comprises a wafer stack formed by a plurality of wafers that are bonded, and the wafer stack comprises the chip stack in each of the bonding sub-structures, and the chips stacks of the bonding sub-structures are arranged in an array in the wafer stack.

6. A method for manufacturing a bonding structure, comprising:
providing a bottom wafer in which chips are arranged in an array, wherein a dielectric bonding layer is formed on the bottom wafer;
providing one or more to-be-bonded wafers, wherein other chips are arranged in an array in each of the one or more to-be-bonded wafers, and another dielectric bonding layer is formed on each of the one or more to-be-bonded wafers; and
bonding the one or more to-be-bonded wafers sequentially on the bottom wafer via the dielectric bonding layer and the another dielectric bonding layer to form a wafer stack comprising an array of chip stacks and electrical vertical interconnections in each of the chip stacks, wherein the chip stacks comprises the chips in the bottom wafer and the other chips in the one or more to-be-bonded wafers, each of the chip stack comprises a plurality of layers of chips, and each layer of the plurality of layers comprises an interconnection layer;
wherein for each of the one or more to-be-bonded wafers, the method further comprises: forming one or more through silicon vias and a rewiring layer electrically connected to the one or more through silicon vias on said to-be-bonded wafer after said to-be-bonded wafer is bonded in the bonding;
wherein the electrical vertical interconnections comprises:
a thorough vertical interconnection that is electrically connected to the interconnection layer in each layer of the plurality of layers, and
one or both of:
a partial vertical interconnection that is electrically connected to the interconnection layer in each layer of a part of the plurality of layers, and
a single vertical interconnection that is electrically connected to the interconnection layer in a single layer of the plurality of layers.

7. The method according to claim 6, wherein for at least one of the one or more to-be-bonded wafers, the rewiring layers is connected to different through silicon vias of the one or more through silicon vias, and the different through silicon vias are located at a same side of the rewiring layer and have different lengths.

8. The method according to claim 6, further comprising:
forming a pad on the rewiring layer of a topmost one of the one or more to-be-bonded wafers.

9. The method according to claim 6, further comprising:
dicing the wafer stack to separate the chip stacks.

10. A method for manufacturing a bonding structure, comprising:
providing a bottom wafer in which chips are arranged in an array, wherein a first hybrid bonding structure is formed on the bottom wafer, the hybrid bonding structure comprises a first dielectric bonding layer and a first metal bonding pad in the dielectric bonding layer, and a part of an interconnection layer in the bottom wafer is electrically connected to the metal bonding pad;
providing one or more to-be-bonded wafers, wherein other chips are arranged in an array in each of the one or more to-be-bonded wafers, a second hybrid bonding structure comprising a second dielectric bonding layer and a second metal bonding pad in the second dielectric bonding layer is formed on each of the one or more to-be-bonded wafers, and a second interconnection layer in each of the one or more to-be-bonded wafer is electrically connected to the second metal bonding pad;
bonding the one or more to-be-bonded wafers sequentially on the bottom wafer via the hybrid bonding structure and the second hybrid bonding structure, to form a wafer stack comprising an array of chip stacks and electrical vertical interconnections in each of the chip stacks, wherein the chip stacks comprises the chips in the bottom wafer and the other chips in the one or more to-be-bonded wafers, each of the chip stack comprises a plurality of layers of chips, and each layer of the plurality of layers comprises an interconnection layer;
wherein for each of the one or more to-be-bonded wafers, the method further comprises: forming one or more through silicon vias on said to-be-bonded wafer after said to-be-bonded wafer is bonded in the bonding;
wherein when a quantity of the to-be-bonded wafer is more than one, for each of the one or more to-be-bonded wafers except a topmost one, after forming the one or more through silicon vias, the method further comprises:
forming a third hybrid bonding structure on the one or more through silicon vias, where the third hybrid bonding structure comprises a third dielectric bonding layer and a third metal bonding pad in the third dielectric bonding layer, and one of the one or more through silicon vias in said to-be-bonded wafer is electrically connected to the third metal bonding pad; and
wherein the electrical vertical interconnections comprise:
a thorough vertical interconnection that is electrically connected to an to the interconnection layer in each layer of the plurality of layers, and
one or both of:
a partial vertical interconnection that is electrically connected to the interconnection layer in each layer of a part of the plurality of layers, and
a single vertical interconnection that is electrically connected to the interconnection layer in a single layer of the plurality of layers.

11. The method according to claim 10, wherein for each of the one or more to-be-bonded wafers, after forming the one or more through silicon vias, the method further includes:
forming a rewiring layer on the one or more through silicon vias.

12. The method according to claim 11, further comprising:
forming a pad on the rewiring layer of the topmost one of the one or more to-be-bonded wafers.

13. The method according to claim 10, further comprising:
dicing the wafer stack to separate the chip stacks.
